(19) United States
(12) Patent Application Publication
(10) Pub. No.: US 2026/0012143 A1
(43) Pub. Date: Jan. 8, 2026

(54) AMPLIFIER WITH INPUT POWER PROTECTION

(71) Applicant: SKYWORKS SOLUTIONS, INC., Irvine, CA (US)

(72) Inventors: Joseph Anton Pusl, III, Encinitas, CA (US); Vrushik Chiman Amrutiya, Lowell, MA (US); Lui Ray Lam, Lexington, MA (US); Andrew Raymond Chen, Newton, MA (US)

(21) Appl. No.: 19/072,170

(22) Filed: Mar. 6, 2025

Related U.S. Application Data
(60) Provisional application No. 63/562,331, filed on Mar. 7, 2024.

(51) Int. Cl. H03F 1/52; H03F 1/22

(52) U.S. Cl. CPC H03F 1/523; H03F 1/223; H03F 2200/294; H03F 2200/444; H03F 2200/451

(57) ABSTRACT

An amplifier circuit for amplifying a radio frequency signal. The amplifier circuit includes an input node, an output node, an amplifier disposed between the input node and the output node, a bias circuit configured to provide a bias signal to the amplifier via a supply node, and a protection circuit. The protection circuit is configured to detect, at a detection node, a voltage the radio-frequency signal received at the input node. The protection circuit further configured to enable a protection mode when the detected voltage is greater than a first threshold value and to disable the protection mode when the detected voltage is less than a second threshold value that is less than the first threshold value, the protection circuit including a first switch disposed between the detection node and the supply node, the protection circuit including a second switch disposed between the supply node and a ground.

### CROSS-REFERENCE TO RELATED APPLICATIONS

This application claims priority under 35 U.S.C. § 119 (e) to U.S. Provisional Patent Application 63/562,331 titled AMPLIFIER WITH INPUT POWER PROTECTION, filed on Mar. 7, 2024, and hereby incorporated by reference in its entirety for all purposes.

### BACKGROUND

### Field

Aspects and embodiments of the present disclosure relate to electronic systems, and in particular, to a power protection for amplifiers.

### Description of the Related Technology

In electronics applications, an amplifier is utilized to amplify a signal such as a radio-frequency (RF) signal. Such an amplified signal can be further processed in, for example, a receiver circuit.

### SUMMARY

In accordance with an aspect of the present disclosure, an amplifier circuit for amplifying a radio frequency signal is provided. The amplifier circuit includes an input node, an output node, an amplifier disposed between the input node and the output node, a bias circuit configured to provide a bias signal to the amplifier via a supply node, and a protection circuit. The protection circuit is configured to detect, at a detection node, a voltage the radio-frequency signal received at the input node. The protection circuit further configured to enable a protection mode when the detected voltage is greater than a first threshold value and to disable the protection mode when the detected voltage is less than a second threshold value that is less than the first threshold value, the protection circuit including a first switch disposed between the detection node and the supply node, the protection circuit including a second switch disposed between the supply node and a ground.

In one example the input node is configured to be coupled to an antenna. In another example, when the protection mode is enabled, the first switch is configured to be open and the second switch is configured to be closed.

In another example, the amplifier is a low-noise amplifier configured to support a receive operation. In accordance with this example, the amplifier circuit may further comprise a third switch disposed between the input node and the detection node, the third switch being configured to be closed while the receive operation is activated. In yet a further example, the amplifier circuit further comprises a fourth switch coupled to the detecting node that is configured to be open when a receive operation is deactivated.

In another example, the amplifier circuit further comprises a diode-based electrostatic discharge diode protection circuit disposed between the supply node and the ground, in parallel to the second switch.

In another example, the amplifier includes a cascode arrangement of a first transistor and a second transistor, the first transistor having an input coupled to the input node, the second transistor coupled to the first transistor and having an output coupled to the output node. In a further example, the first transistor and the second transistor are field-effect transistors each having a gate, a drain and a source. In at least some examples the first transistor is implemented as a common source device, and the second transistor is implemented as a common gate device, such that the gate of the first transistor is coupled to the input node, the drain of the first transistor is coupled to the source of the second transistor, and the drain of the second transistor is coupled to the output node. In at least some examples, the source of the first transistor is coupled to ground and the gate of the second transistor is coupled to a node having a gate potential.

In some examples, the amplifier circuit further comprises a fourth switch coupled to the detecting node that is configured to be open when a receive operation is deactivated.

In another example, the bias circuit is configured to provide the bias signal to the input of the first transistor through a bias resistance, the bias circuit including a current mirror, such that the bias signal is representative of an output of the current mirror.

According to another aspect of the present disclosure, a radio frequency module is provided. The radio frequency module comprises a packaging board configured to receive a plurality of components, and an amplifier circuit for amplifying a radio frequency signal implemented on the packaging board. The amplifier circuit includes an input node, an output node, an amplifier disposed between the input node and the output node, a bias circuit configured to provide a bias signal to the amplifier via a supply node, and a protection circuit. The protection circuit is configured to enable a protection mode when the detected voltage is greater than a first threshold value and to disable the protection mode when the detected voltage is less than a second threshold value that is less than the first threshold value, the protection circuit including a first switch disposed between the detection node and the supply node, the protection circuit including a second switch disposed between the supply node and a ground.

In one example, the input node is configured to be coupled to an antenna and wherein the amplifier is a low-noise amplifier configured to support a receive operation.

In another example, when the protection mode is enabled, the first switch is configured to be open and the second switch is configured to be closed.

In yet a further example, the amplifier circuit further comprises a third switch disposed between the input node and the detection node, and the third switch configured to be closed while the receive operation is activated. In yet a further example, the amplifier circuit further comprises a fourth switch coupled to the detecting node that is configured to be open when a receive operation is deactivated.

In another example, the amplifier circuit further comprises a diode-based electrostatic discharge diode protection circuit disposed between the supply node and the ground, in parallel to the second switch.

In another example, the amplifier includes a cascode arrangement of a first transistor and a second transistor, the first transistor having an input coupled to the input node, the second transistor coupled to the first transistor and having an output coupled to the output node, wherein the first transistor and the second transistor are field-effect transistors each having a gate, a drain and a source, and wherein the first transistor is implemented as a common source device and the second transistor is implemented as a common gate device, such that the gate of the first transistor is coupled to the input node, the drain of the first transistor is coupled to the source of the second transistor, and the drain of the second transistor is coupled to the output node.

In yet another example, the bias circuit is configured to provide the bias signal to the input of the first transistor through a bias resistance, the bias circuit including a current mirror, such that the bias signal is representative of an output of the current mirror.

### BRIEF DESCRIPTION OF THE DRAWINGS

FIG. 1 depicts an amplifier circuit having an amplifier and an input power protection circuit.

FIG. 2 shows an amplifier circuit that can be a more specific example of the amplifier circuit of FIG. 1.

FIG. 3 shows an example amplifier circuit having a conventional protection circuit implemented as an electro-static discharge (ESD) protection circuit coupled to an input path of an amplifier.

FIG. 4A shows that in some embodiments, an amplifier circuit can be implemented to include a protection circuit configured to detect, with a detector, a high electrical power condition along an input path to an amplifier.

FIG. 4B shows an amplifier circuit having a similar architecture as the amplifier circuit of FIG. 4A, but where a cascode amplifier includes first and second bipolar junction transistors.

FIG. 5 illustrates a schematic diagram of an amplifier circuit according to an embodiment that can be a more specific example of the amplifier circuit of FIG. 4A.

FIG. 6 shows the amplifier circuit of FIG. 5 where the protection circuit is configured for a normal operating mode.

FIG. 7 shows the same amplifier circuit where the protection circuit is configured for a protection mode upon detection of a high power condition at the input of the amplifier.

FIG. 8 shows various signal traces associated with the common source transistor (Q1) of the amplifier circuit without the protection circuit shown in FIG. 5.

FIG. 9 shows various signal traces associated with the common gate transistor (Q2) of the amplifier circuit with the protection circuit shown in FIG. 5.

FIG. 10 shows that in some embodiments, substantially all of a protection circuit having one or more features as described herein can be implemented on a die that includes the corresponding amplifier.

FIG. 11 shows that in some implementations, one or more features described herein can be included in a module.

FIG. 12 depicts an example wireless device having one or more advantageous features described herein.

FIG. 13 shows an example where the wireless device of FIG. 14 can benefit with a protection circuit having one or more features as described herein.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

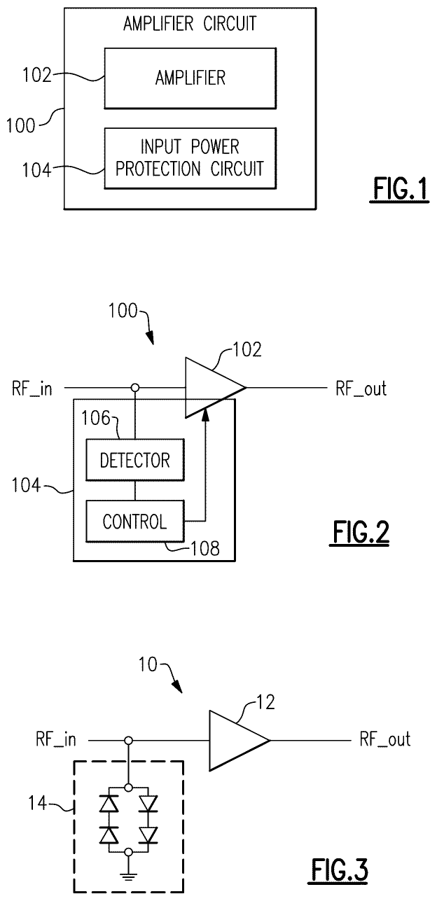

FIG. 1 depicts an amplifier circuit 100 having an amplifier 102 and an input power protection circuit 104. Various features associated with such an amplifier circuit are described herein. While various examples are described herein in the context of protecting the amplifier circuit based on an input of the amplifier, it will be understood that one or more features of the present disclosure can also be implemented in other applications with respect to an amplifier, in non-amplifier applications, etc.

FIG. 2 shows an amplifier circuit 100 that can be a more specific example of the amplifier circuit 100 of FIG. 1, in the context of providing circuit protection based on an input of an amplifier 102. Accordingly, such an amplifier circuit is shown to include an input power protection circuit 104 coupled to an input signal path. Such an input signal path is shown to allow a radio-frequency (RF) signal (RF_in) to be provided as an input for the amplifier 102 to thereby generate an amplified RF signal (RF_out).

FIG. 2 shows that in some embodiments, the input power protection circuit 104 can include a detector component 106 and a control component 108. For the purpose of description, it will be understood that a component can include one or more devices, one or more circuits, or any combination thereof, implemented to provide the described functionality. Accordingly, and as described herein, the detector component 106 can be configured to detect a condition associated with the input RF signal (RF_in) and generate an output representative of the condition. The control component 108 can be configured to generate one or more control signals based on the output of the detector component 106, and such control signal(s) can be utilized to configure the operation of the amplifier 102 so as to prevent or reduce the likelihood of damage that may arise from the condition associated with the input signal. More specific examples of such detection and control functionalities are described herein in greater detail.

It is noted that in an example wireless application such as a cellular phone, a receiver circuit typically includes a low-noise amplifier (LNA) configured to amplify a weak signal received through an antenna and routed through a front-end antenna switch/filter network. Such an LNA is typically configured to provide high gain, low noise figure (NF), and other performance features, such as a high input third order intercept (IIP3) (e.g., over frequencies from 600 MHz to 5000 MHz).

To achieve these high performance characteristics, such an LNA can be fabricated utilizing, for example, a CMOS RFIC (complementary metal-oxide-semiconductor radio-frequency integrated circuit) process which utilizes narrow channel (e.g., <90 nm), thin gate oxide (e.g., <1.8 nm) NMOS (N-type MOS) devices for a common source input stage. Since the gate oxide is relatively thin, these devices can fail due to time-dependent dielectric breakdown (TDDB) which can occur if the device is operated close to or beyond a specified maximum lifetime gate voltage (e.g., ^{˜}1.5V).

It is also noted that a cellular phone receiver can be subjected to high power RF signal(s) (e.g., up to 23 dBm) when in close proximity to one or more other cellular handsets. Under such a condition, peak voltages as high as +/−3.6V can exist on the NMOS gate of the above-referenced LNA, severely degrading the lifetime of the corresponding device.

In many wireless designs, damage or permanent performance degradation that results from an electrical condition such as the foregoing high power voltage condition is not acceptable. Accordingly, some wireless designs include a protection circuit that provides limiting or clamping functionality at an input of an LNA. FIG. 3 shows an example amplifier circuit 10 having a conventional protection circuit implemented as an electro-static discharge (ESD) protection circuit 14 coupled to an input path of an LNA 12.

In the example of FIG. 3, the ESD protection circuit 14 is shown to include an anti-parallel combination of diodes that couples the input path of the LNA 12 and ground. Such a combination of diodes can be utilized to limit or clamp the input RF level to some safe level. To provide such protection functionality, single stack, large periphery diodes are typically required. However, such diodes typically load the input path with a large parasitic capacitance that degrades the input impedance match to result in degradation in gain and noise figure performance. Such excessive diode parasitic capacitance can also become even more unmanageable as the operating frequency is increased.

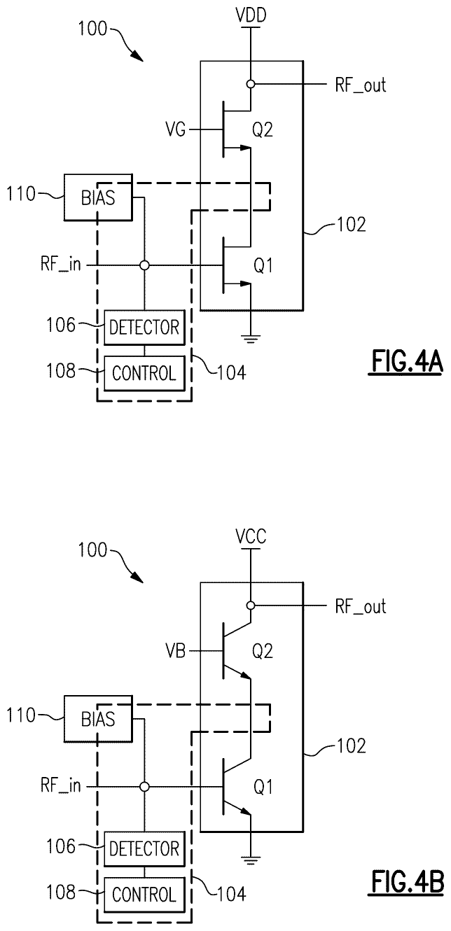

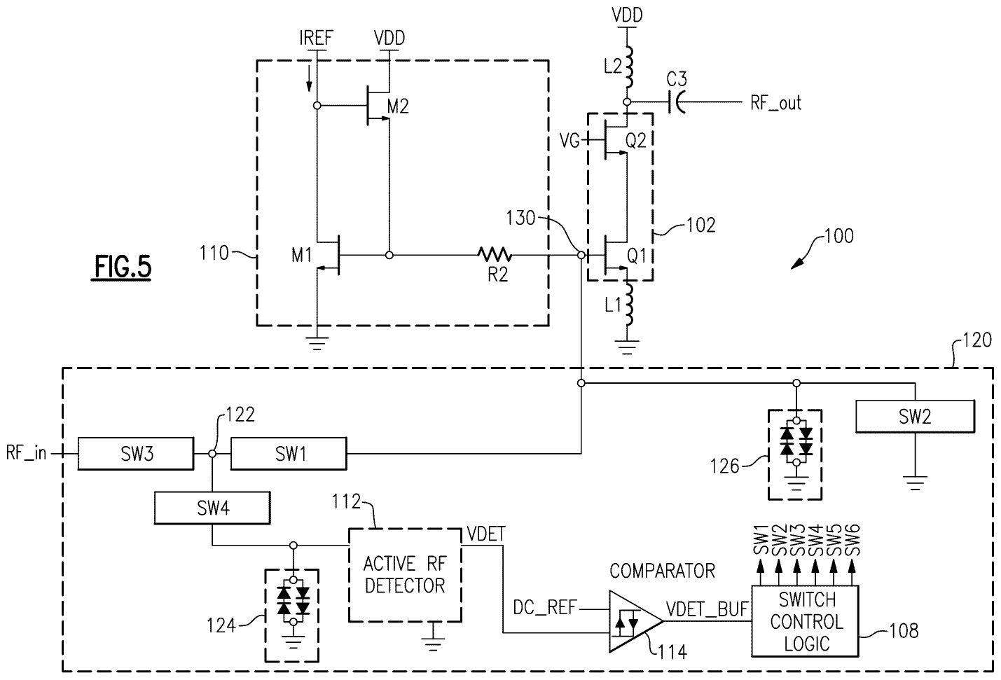

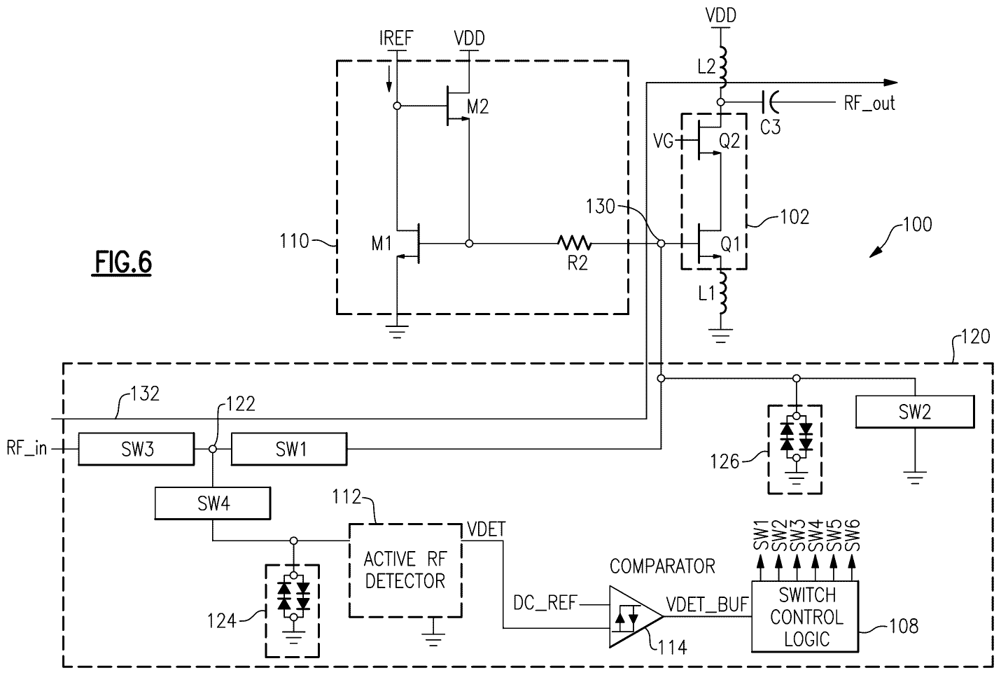

In some embodiments, the amplifier circuit 100 of FIG. 2 can be configured such that the protection circuit 104 provides protection against high electrical power presented to the input of the amplifier 102 without the diode-based ESD protection circuit 14 of FIG. 3. For example, FIG. 4A shows that in some embodiments, an amplifier circuit 100 can be implemented to include a protection circuit 104 configured to detect, with a detector 106, a high electrical power condition along an input path to an amplifier 102. The protection circuit 104 is shown to further include a control component 108 configured to control operation of one or more parts of the amplifier circuit 100. Examples of such detector and control components are described herein in greater detail.

In the example of FIG. 4A, the amplifier 102 is configured as a cascode amplifier having a cascode arrangement of a first transistor Q1 and a second transistor Q2. For example, the first transistor Q1 can be implemented as a common source (CS) stage where an input signal (RF_in) is provided to a gate of Q1, and an amplified signal is output through a drain of Q1, with a source of Q1 being coupled to ground. The second transistor Q2 can be implemented as a common gate (CG) stage where the amplified signal from Q1 is provided to a source of Q2, and a further amplified signal is output through a drain of Q2, with a gate of Q2 being provided with a gate voltage VG.

In the example of FIG. 4A, the amplifier circuit 100 can further include a bias circuit 110 configured to provide, for example, a bias signal to the gate of Q1. Accordingly, such a bias circuit can be coupled to the input path that routes the input signal RF_in. In the example of FIG. 4A, the amplifier 102 is shown to be provided with a supply voltage VDD to the drain of the second transistor Q2.

In some embodiments, and as depicted in FIG. 4A, the protection circuit 104 can be configured such that the control component 108 controls operation of the input path, operation of the bias circuit, and/or operation of the cascode amplifier 102. Examples related to such protection operations are described herein in greater detail.

It is noted that the example of FIG. 4A and the more specific examples of FIGS. 5-7 are described in the context of a cascode amplifier utilizing field-effect transistors (FETs). It will be understood that in some embodiments, one or more features of the present disclosure can also be implemented for non-cascode configured amplifiers. It will also be understood that in some embodiments, one or more features of the present disclosure can also be implemented utilizing other types of transistors, including bipolar-junction transistors (BJTs).

For example, FIG. 4B shows an amplifier circuit 100 having a similar architecture as the amplifier circuit 100 of FIG. 4A, but where a cascode amplifier 102 includes first and second BJTs Q1, Q2. More particularly, the first transistor Q1 can be implemented as a common emitter stage where an input signal (RF_in) is provided to a base of Q1, and an amplified signal is output through a collector of Q1, with an emitter of Q1 being coupled to ground. The second transistor Q2 can be implemented as a common base stage where the amplified signal from Q1 is provided to an emitter of Q2, and a further amplified signal is output through a collector of Q2, with a base of Q2 being provided with a base voltage VB.

In the example of FIG. 4B, the amplifier circuit 100 can further include a bias circuit 110 configured to provide, for example, a bias signal to the base of Q1. Accordingly, such a bias circuit can be coupled to the input path that routes the input signal RF_in. In the example of FIG. 4B, the amplifier 102 is shown to be provided with a supply voltage VCC to the collector of the second transistor Q2.

FIG. 5 illustrates a schematic diagram of an amplifier circuit 100 according to an embodiment that can be a more specific example of the amplifier circuit of FIG. 4A. In the example of FIG. 5, an amplifier 102 is shown to include a cascode arrangement of first and second transistors Q1, Q2, similar to the example of FIG. 4A. An input signal (RF_in) is shown to be provided to a gate of Q1 through a third switch SW3 and a first switch SW1, and an amplified signal is shown to be provided as an output (RF_out) through a drain of Q2 and a DC-block capacitance C3. The amplifier 102 may be a low-noise amplifier (LNA) configured to support a receive operation.

In the example of FIG. 5, the amplifier circuit 100 according to an embodiment may include an input node (RF_in), an output node (RF_out), and an amplifier 102 disposed between the input node (RF_in) and the output node (RF_out). The input node (RF_in) may be configured to be coupled to an antenna.

The amplifier circuit 100 may include a bias circuit 110 configured to provide a bias signal to the amplifier 102 via a supply node 130. In the example of FIG. 5, a bias circuit is generally indicated as bias circuit 110, and is shown to include a current mirror where a reference current IREF can be replicated through a mirror arrangement of a transistor M1 on the IREF side and a transistor M2 on a supply (e.g., VDD) side. The mirrored current from the supply can be provided to the gate of Q1 of the amplifier 102 through a bias resistance R2 for operation of the amplifier 102.

The amplifier circuit 100 may include a (multi-stage) protection circuit 120 configured to detect a voltage of the radio-frequency signal, and to enable or disable a protection mode based on the detected voltage. According to an embodiment, the multi-stage protection circuit 120 may include a detector 112 to detect the voltage of the radio-frequency signal. The voltage can be detected at the detection node 122 disposed between the first switch SW1 and the third switch SW3. The detection node 122 may be coupled to the input node (RF_in) via the third switch SW3. The multi-stage protection circuit 120 may further include a fourth switch SW4 coupled to the detection node 122. The fourth switch SW4 may be disposed between the detection node 122 and the detector 112, and be configured to be open when the receive operation is deactivated.

As described herein, such a detector 112 can sample and measure a detected voltage VDET representative of a peak value of an RF signal at the detection node 122 on the input path. For example, the detector 112 may include a diode that can limit flow of current from the sampled RF signal to a forward direction, and a capacitor that can be charged by the current to reach a peak voltage. Furthermore, a resistor can be implemented to allow the charged capacitor to discharge. According to an embodiment, the detector 112 may be an active RF detector, which enables one to achieve a lower threshold value than a diode-base RF peak detector. The lower threshold is desirable due to the impedance level (for example, 50 Ohms characteristic impedance) at the node where the detector 112 is placed and the resultant voltage swings seen at that node. The voltage swing seen at the input/gate of the amplifier 102 is much higher than at the detection node 122 because the amplifier gate has a much higher impedance, and the higher voltage could cause harm to the amplifier 102.

In some embodiments, the detected voltage VDET from the detector 112 can be provided to a comparator 114. The detector 112 may include a rectifier (not shown). The rectifier may be configured to produce VDET (a DC output signal) which is fed to the comparator 114. As shown in FIG. 5 and FIG. 6, a DC reference can be input to the comparator 114. The comparator 114 can output a signal VDET_BUF (e.g., high or low) based on the value of the input signal VDET in comparison to the DC reference. The value of the DC reference can be set by a user in advance. For example, if the value of VDET is greater than a first threshold value, the output signal VDET_BUF can be set to be high, and based on such a high signal, a control action can be enabled to protect the amplifier circuit 100. If the value of VDET is less than a second threshold value, the output signal VDET_BUF can be set to be low, and based on such a low signal, the foregoing control action can be disabled to allow the amplifier circuit 100 to return to normal operation.

In some embodiments, the first threshold value and the second threshold value utilized by the comparator 114 can be different. In some embodiments, such different threshold values for low-to-high and high-to-low transitions of the output signal VDET_BUF can be provided by a Schmitt trigger implemented as the foregoing comparator 114. Such a Schmitt trigger can include a hysteresis property to provide such different threshold values. Examples of enabling and disabling of protection of the amplifier circuit 100 based on such hysteresis property are described herein in greater detail.

In the example of FIG. 5, the detector 112 and the comparator 114 can be considered to be an example of the detector component 106 of FIG. 4A. In FIG. 5, a switch control logic circuit 108 can be considered to be an example of the control component 108 of FIG. 4A. In some embodiments, such a switch control logic circuit can provide a first set of switch control signals for the switches SW1, SW2, SW3, SW4 if the VDET_BUF from the comparator 114 is high, and provide a second set of switch control signals for the same switches if the VDET_BUF from the comparator 114 is low. According to an embodiment, the switch control logic circuit 108 may include a delay circuit (not shown). The delay of sufficient length embodied by the delay circuit is desirable in the presence of a modulated RF input signal. Without a delay, a modulated RF input signal will cause the circuit/loop to oscillate between the OFF and ON states. Examples of such switching control functionality are described herein in greater detail.

The protection circuit 120 may be configured to enable a protection mode when the detected voltage VDET is greater than the first threshold value. The protection circuit 120 may be configured to disable the protection mode when the detected voltage is less than the second threshold value that is less than the first threshold value. The protection circuit 120 includes the first switch SW1, which is referred to as a series switch, disposed between the detection node 122 and the supply node 130. The protection circuit 120 may further include a second switch SW2, which is referred to as a shunt switch, disposed between the supply node 130 and a ground. According to an embodiment, when the protection mode is enabled, the first switch SW1 may be configured to be open and the second switch SW2 may be configured to be closed. Eventually, the amplifier 102 may be turned off, and it will keep swings at the amplifier 102 as low as possible.

According to some embodiments, the circuit 120 provides advanced protection measures to protect the amplifier 102 using the first switch SW1 and the second SW2 in multiple stages. More specifically, the switches turn ON faster than they turn OFF due to use of a negative voltage generator (NVG) to provide negative or logic low level voltages and use of a low dropout regulator (LDO)/positive voltage generator (PVG) to provide positive or logic high level voltages, with the NVG being weaker than the LDO)/PVG. Therefore, it is desirable to dispose a shunt switch (SW2) to be turned ON in the protection mode in combination with the series switch (SW1) to be turned OFF for more reliable protection operation. According to an embodiment, the first switch SW1 turns off slowly due to being supplied, for example, by the NVG, and then the switch control logic (for example, Schmitt trigger or other Sampling logic) is used to determine that the first switch SW1 is turned off sufficiently to allow the second switch SW2 to then be turned on.

The third switch SW3 may be closed during the receive operation. That is, when the receive operation is activated, the third switch SW3 may be closed regardless of whether the protection mode is enabled or disabled. The third switch SW3 may be open when the receive operation is deactivated, and the transmit operation is activated. Adding the third switch SW3 between the input node and the detection node enables more flexible TX/RX transition operation.

The protection circuit 120 may further include a diode-based electrostatic discharge diode (ESD) protection circuit 126 disposed between the supply node 130 and the ground, in parallel to the second switch SW2. It will be understood that an amplifier circuit 100 having one or more features as described herein may or may not include such a diode-based ESD protection circuit 126.

In some embodiments, since the protection circuit 120 can provide protection against high input power, the diode-based ESD protection circuit 126 can be further configured appropriately so that it does not need to handle high input power. For example, diodes of the ESD protection circuit 126 can be configured as smaller multi-stack devices to meet lower power human body model (HBM)/charge device model (CDM) protection requirements, thereby resulting in a reduced parasitic capacitance for the amplifier circuit 100.

The protection circuit 120 may further include an additional diode-based ESD protection circuit 124 disposed between the fourth switch SW4 and the detector 112. The fourth switch SW4 and the additional diose-based ESD protection circuit 124 may provide the advanced protection scheme for the detector 112.

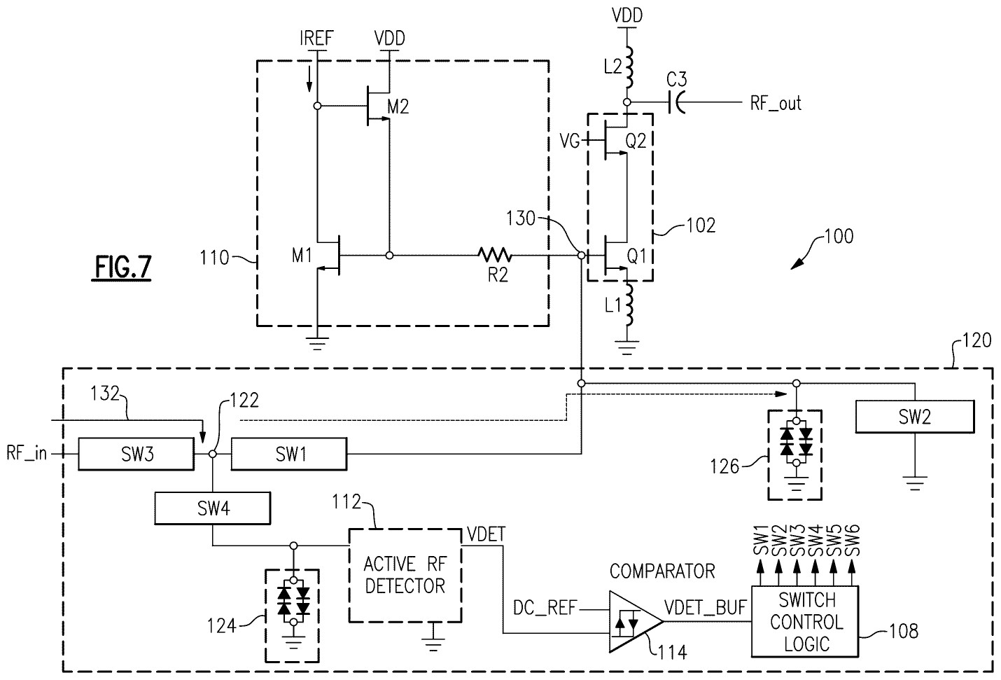

FIG. 6 shows the amplifier circuit 100 of FIG. 5 where the protection circuit 120 is configured for a normal operating mode, and FIG. 7 shows the same amplifier circuit 100 where the protection circuit 120 is configured for a protection mode upon detection of a high power condition at the input of the amplifier 102.

Referring to the normal operating mode of FIG. 6, an RF signal is shown to be provided to Q1 as an input; Q1 is shown to provide a partially amplified signal to Q2; and Q2 is shown to provide an amplified signal as an output of the amplifier 102. In FIG. 6, a path taken by the input signal (RF_in) to become the output signal (RF_out) is depicted as 132.

Referring to the protection mode of FIG. 7, an RF signal present at the input path can include, for example, a high power signal being transmitted from a nearby device. Accordingly, the high power signal is rejected by the first switch SW1 along the signal path as a first stage. Furthermore, in case there is some current leakage through the first switch SW1 before the first switch SW1 is completely open, the leakage signal is shown to be shunted to ground through the shunt path through SW2. Even when there is a diode-based ESD protection circuit 126 already, the second switch SW2 provides more prompt reaction as soon as the protection mode is enabled.

More particularly, it is noted that in the protection mode of FIG. 7, the first switch SW1 can be opened to disable operation of delivering the high power signal to the amplifier 102, and the second switch SW2 can be closed to shunt the signal on the signal path leaked through the first switch SW1 to ground.

Referring to FIGS. 6 and 7, the foregoing normal operating mode and the protection mode can be controlled by the switch control logic circuit 108 providing appropriate switch control signals. For example, a given switch control signal can be a low signal or a low bit 0 to open the corresponding switch, or a high signal or a high bit 1 to close the corresponding switch.

As described herein, a comparator such as the Schmitt trigger of FIG. 5 can be configured so that the protection mode is triggered for the amplifier circuit 100 when the detected voltage VDET exceeds a first threshold voltage Vlh (e.g., when VDET>Vlh), and the amplifier circuit 100 reverts back to the normal operating mode when VDET falls below a second threshold voltage Vhl (e.g., when VDET<Vhl). In some embodiments, the first threshold voltage can be greater than the second threshold voltage so as to, for example, prevent a chattering effect where the amplifier circuit 100 is too sensitive to transitions between the normal operating mode and the protection mode.

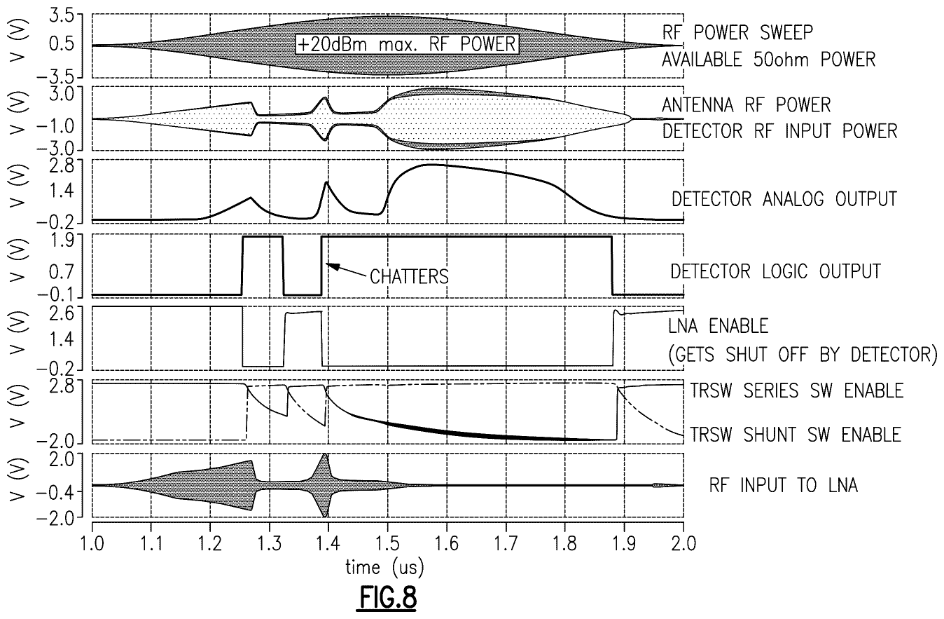

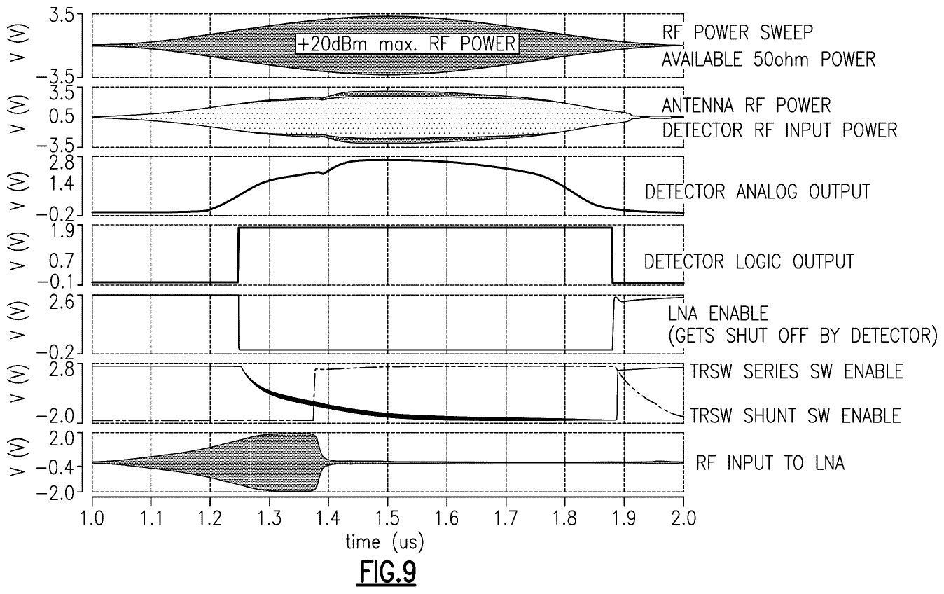

FIG. 8 shows various signal traces associated with the common source transistor (Q1) of the amplifier circuit without the protection circuit shown in FIG. 5. FIG. 9 shows various signal traces associated with the common gate transistor (Q2) of the amplifier circuit with the protection circuit shown in FIG. 5.

Referring to FIGS. 8-9, without the protection circuit according to an embodiment of the present disclosure, RF switches turn ON faster than they turn OFF due to NVG being weaker than LDO/PVG. Therefore, it is needed to wait until series SWs are OFF before engaging shunt SW. As can be seen from FIG. 8, there is a chattering effect until the series SW is completely open. In FIG. 9, the chattering effect has been removed.

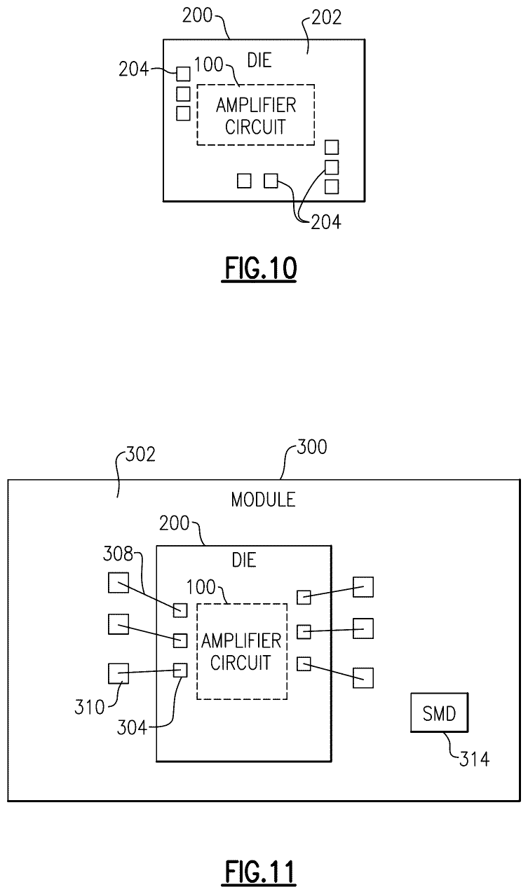

FIG. 10 shows that in some embodiments, substantially all of a protection circuit having one or more features as described herein can be implemented on a die that includes the corresponding amplifier. Thus, in FIG. 10, a die 200 is shown to include an amplifier circuit 100 having an amplifier and a protection circuit as described herein. Such an amplifier circuit can be implemented on a semiconductor substrate 202, and various connections for operations of the die 200 can be supported by, for example, contact pads 204.

In some embodiments, the die 200 of FIG. 10 can be configured to support formation and operation of FET devices or FET-based devices. For example, transistors Q1, Q2, M1, M2, various switches, diode D1, and transistors associated with the Schmitt trigger can be implemented as MOSFET devices or MOSFET-based devices. In some embodiments, such MOSFET devices can be NMOS devices.

As described herein, various switches can be operated to allow the amplifier circuit to be in a normal operating mode or a protection mode. As also described herein, use of a comparator having a hysteresis property, such as a Schmitt trigger, provides a “dead zone” where the protection mode remains enabled to prevent a chattering effect. In some embodiments, some or all of the foregoing switches can be configured to support such a dead zone. For example, switches SW1, SW3 and SW4 that are closed during the normal operating mode can be sized appropriately such that the detected voltage VDET resides in the Schmitt trigger's dead zone, thereby preventing the protection mode being prematurely disabled.

In some embodiments, other non-transistor elements of the amplifier circuit can also be implemented to be parts of the die 200. For example, various resistances, inductances and capacitances can be implemented utilizing respective on-die technologies.

It is noted that in the context of the amplifier circuit being a receive amplifier circuit (e.g., with an LNA), a protection circuit as described herein can be configured to support various frequency ranges, including LNAs operating at MB/HB/UHB frequencies. As described herein, such a protection circuit disables LNA current during the protection mode, and such a feature prevents die metallization from overheating and possibly melting.

It is also noted that a protection circuit as described herein consumes little or no current, and requires a relatively small amount of additional die area. For example, the detector and comparator (e.g., 112, 114 in FIG. 5) can be implemented in an area of about 630 μm2 utilizing, for example, CMOS technologies.

In some embodiments, an amplifier circuit as described herein can be configured to support higher frequency applications (e.g., >5 GHz, millimeter waves). For example, an LNA can utilize CMOS processes with smaller gate lengths and thinner gate oxides. Such a configuration can result in, for example, time-dependent dielectric breakdown (TDDB) gate voltages, thereby potentially reducing the maximum lifetime of the LNA device. In some embodiments, a protection circuit as described herein can accommodate these lower clamp levels without sacrificing the performance of the LNA.

In some implementations, one or more features described herein can be included in a module. FIG. 11 depicts an example module 300 having a packaging substrate 302 that is configured to receive a plurality of components. In some embodiments, such components can include a die 200 having one or more features as described herein. For example, the die 200 can include an amplifier circuit 100 that includes a protection circuit as described herein. A plurality of connection pads 304 can facilitate electrical connections such as wirebonds 308 to connection pads 310 on the substrate 302 to facilitate passing of various power and signals to and from the die 200.

In some embodiments, other components can be mounted on or formed on the packaging substrate 302. For example, one or more surface mount devices (SMDs) (314) can be implemented. In some embodiments, the packaging substrate 302 can include a laminate substrate.

In some embodiments, the module 300 can also include one or more packaging structures to, for example, provide protection and facilitate easier handling of the module 300. Such a packaging structure can include an overmold formed over the packaging substrate 302 and dimensioned to substantially encapsulate the various circuits and components thereon.

It will be understood that although the module 300 is described in the context of wirebond-based electrical connections, one or more features of the present disclosure can also be implemented in other packaging configurations, including flip-chip configurations.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

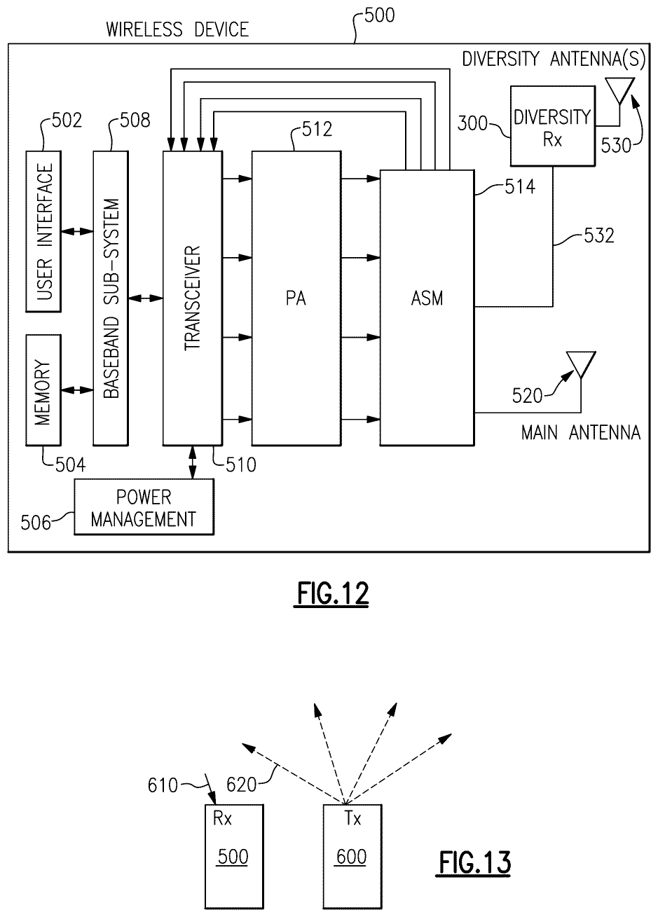

FIG. 12 depicts an example wireless device 500 having one or more advantageous features described herein. In some embodiments, a module having one or more features as described herein can be implemented as, for example, a diversity receive module 300 in close proximity to a diversity antenna 530, or a module configured to receive a signal from any antenna. Such a module can be configured to provide one or more desirable features as described herein.

In the example of FIG. 12, power amplifiers (PAS) in a PA module 512 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management component 506 that is configured to manage power for the operation of the wireless device 500. Such power management can also control operations of the baseband sub-system 508 and other components of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example of FIG. 12, the DRx module 300 can be implemented between one or more diversity antennas (e.g., diversity antenna 530) and the ASM 514. Such a configuration can allow an RF signal received through the diversity antenna 530 to be processed with little or no loss of and/or little or no addition of noise to the RF signal from the diversity antenna 530. Such processed signal from the DRx module 300 can then be routed to the ASM through one or more signal paths.

In the example of FIG. 12, a main antenna 520 can be configured to, for example, facilitate transmission of RF signals from the PA module 512. In some embodiments, receive operations can also be achieved through the main antenna.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

As described herein, in some embodiments, an amplifier circuit with a protection circuit can be configured for receive operations. As also described herein, such a protection circuit can prevent damage to the amplifier circuit in situations where a strong signal is received and presented to the amplifier circuit.

FIG. 13 shows an example where the wireless device 500 of FIG. 12 can benefit with the protection circuit (e.g., implemented as part of the receiver module 300). In FIG. 13, a wireless device 500 having such a protection circuit is shown to be receiving an incoming signal 610 (e.g., from a cell tower). In close proximity to the wireless device 500 is another wireless device 600 (that may or may not include a protection circuit) in a transmit operation, thereby transmitting a relatively powerful signal 620. Such a powerful signal can be picked up by the antenna of the wireless device 500 and be presented to its amplifier circuit. As described herein, a protection circuit associated with the amplifier circuit of the device 500 can be operated to protect the amplifier circuit.

Some of the embodiments described above have provided examples in connection with wireless devices or mobile phones. However, the principles and advantages of the embodiments can be used for any other systems or apparatus that have needs for amplifiers.

Such amplifiers can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description is not intended to be exhaustive or to limit aspects and embodiments of the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope of the disclosure.

What is claimed is:

1. An amplifier circuit for amplifying a radio frequency signal comprising:
an input node;
an output node;
an amplifier disposed between the input node and the output node;
a bias circuit configured to provide a bias signal to the amplifier via a supply node; and
a protection circuit configured to detect, at a detection node, a voltage the radio-frequency signal received at the input node, the protection circuit configured to enable a protection mode when the detected voltage is greater than a first threshold value and to disable the protection mode when the detected voltage is less than a second threshold value that is less than the first threshold value, the protection circuit including a first switch disposed between the detection node and the supply node, the protection circuit including a second switch disposed between the supply node and a ground.

2. The amplifier circuit of claim 1 wherein the input node is configured to be coupled to an antenna.

3. The amplifier circuit of claim 1 wherein, when the protection mode is enabled, the first switch is configured to be open and the second switch is configured to be closed.

4. The amplifier circuit of claim 1 wherein the amplifier is a low-noise amplifier configured to support a receive operation.

5. The amplifier circuit of claim 4 further comprising a third switch disposed between the input node and the detection node, the third switch being configured to be closed while the receive operation is activated.

6. The amplifier circuit of claim 1 further comprising a diode-based electrostatic discharge diode protection circuit disposed between the supply node and the ground, in parallel to the second switch.

7. The amplifier circuit of claim 1 wherein the amplifier includes a cascode arrangement of a first transistor and a second transistor, the first transistor having an input coupled to the input node, the second transistor coupled to the first transistor and having an output coupled to the output node.

8. The amplifier circuit of claim 7 wherein the first transistor and the second transistor are field-effect transistors each having a gate, a drain and a source.

9. The amplifier circuit of claim 8 wherein the first transistor is implemented as a common source device, and the second transistor is implemented as a common gate device, such that the gate of the first transistor is coupled to the input node, the drain of the first transistor is coupled to the source of the second transistor, and the drain of the second transistor is coupled to the output node.

10. The amplifier circuit of claim 8 wherein the source of the first transistor is coupled to ground and the gate of the second transistor is coupled to a node having a gate potential.

11. The amplifier circuit of claim 1 further comprising a fourth switch coupled to the detecting node that is configured to be open when a receive operation is deactivated.

12. The amplifier circuit of claim 1 wherein the bias circuit is configured to provide the bias signal to the input of the first transistor through a bias resistance, the bias circuit including a current mirror, such that the bias signal is representative of an output of the current mirror.

13. A radio frequency module comprising:
a packaging board configured to receive a plurality of components;
an amplifier circuit for amplifying a radio frequency signal implemented on the packaging board, the amplifier circuit comprising: an input node, an output node, an amplifier disposed between the input node and the output node, a bias circuit configured to provide a bias signal to the amplifier via a supply node, and a protection circuit configured to detect, at a detection node, a voltage of the radio-frequency signal received at the input node, the protection circuit configured to enable a protection mode when the detected voltage is greater than a first threshold value and to disable the protection mode when the detected voltage is less than a second threshold value that is less than the first threshold value, the protection circuit including a first switch disposed between the detection node and the supply node, the protection circuit including a second switch disposed between the supply node and a ground.

14. The radio frequency module of claim 13 wherein the input node is configured to be coupled to an antenna and wherein the amplifier is a low-noise amplifier configured to support a receive operation.

15. The radio frequency module of claim 13 wherein, when the protection mode is enabled, the first switch is configured to be open and the second switch is configured to be closed.

16. The radio frequency module of claim 13 wherein the amplifier circuit further comprises a third switch disposed between the input node and the detection node, and the third switch configured to be closed while the receive operation is activated.

17. The radio frequency module of claim 16 wherein the amplifier circuit further comprises a fourth switch coupled to the detecting node that is configured to be open when a receive operation is deactivated.

18. The radio frequency module of claim 13 wherein the amplifier circuit further comprises a diode-based electrostatic discharge diode protection circuit disposed between the supply node and the ground, in parallel to the second switch.

19. The radio frequency module of claim 13 wherein:
the amplifier includes a cascode arrangement of a first transistor and a second transistor, the first transistor having an input coupled to the input node, the second transistor coupled to the first transistor and having an output coupled to the output node;
the first transistor and the second transistor are field-effect transistors each having a gate, a drain and a source; and
the first transistor is implemented as a common source device and the second transistor is implemented as a common gate device, such that the gate of the first transistor is coupled to the input node, the drain of the first transistor is coupled to the source of the second transistor, and the drain of the second transistor is coupled to the output node.

20. The radio frequency module of claim 13 wherein the bias circuit is configured to provide the bias signal to the input of the first transistor through a bias resistance, the bias circuit including a current mirror, such that the bias signal is representative of an output of the current mirror.
